(19) United States
(12) Patent Application Publication
(10) Pub. No.: US 2012/0260970 A1
(43) Pub. Date: Oct. 18, 2012

(54) DEVICE FOR CONCENTRATING AND CONVERTING SOLAR ENERGY

(75) Inventor: Harry Wirth, Merzhausen (DE)

(73) Assignee: Fraunhofer-Gesellschaft zur Forderung der Angewandten Forschung E.V., Munchen (DE)

(21) Appl. No.: 13/502,037

(22) PCT Filed: Oct. 11, 2010
(86) PCT No.: PCT/EP2010/006202

§ 371 Date: Jun. 28, 2012

(30) Foreign Application Priority Data
Oct. 13, 2009 (DE) 10 2009 049 228.3

(51) Int. Cl. H01L 31/058; H01L 31/052

(52) U.S. Cl. 136/248; 136/246

(57) ABSTRACT

The invention relates to a device for concentrating and converting solar energy, which has at least one beam splitter of a planar configuration for deflecting solar radiation and at least two devices for the conversion of solar energy which are disposed offset relative to the beam splitter with respect to the direction of incidence of the solar radiation.

The invention relates to a device for concentrating and converting solar energy, which has at least one beam splitter of a planar configuration for deflecting solar radiation and at least two devices for the conversion of solar energy which are disposed offset relative to the beam splitter with respect to the direction of incidence of the solar radiation.

There have been approaches for many years in the field of photovoltaics for concentrating solar radiation in order to minimise the quantity of solar cell material and, on the other hand, to achieve higher efficiency. The principle is based on the fact that solar radiation is concentrated with mirror and/or lenses and directed towards special concentrator solar cells. Hence the photovoltaically active surface is reduced and hence the quantity of expensive solar cell materials which is required.

By concentrating the solar radiation which acts on photovoltaically active surfaces, the costs for the solar current can be reduced. This applies in particular for regions with a high component of direct radiation.

In the state of the art, light-permeable plates with structuring on one side in the manner of linear Fresnel lenses are known for concentrating solar radiation onto PV receivers (US 2003/0201007 A1, DE 101 25 273 A1). These lenses have active facets and inactive facets (“steps”). The lenses function on the basis of light refraction, lenses based on total reflection also being known.

In the case of vertical irradiation of the sheet, the structure must be disposed on the side orientated away from the radiation in order to avoid losses due to the inactive facts (steps). The vertical inactive facets and the acute angles between active and inactive facets of less than 60° are disadvantageous if using economical materials and shaping processes, e.g. by structuring glass, is important.

It is therefore the object of the invention to provide a concentrator arrangement which enables a significant reduction in the surface extension of devices for the conversion of solar energy which are coupled to the concentrators.

This object is achieved by the concentrator having the features of claim 1. The further dependent claims reveal advantageous developments.

According to the invention, a device for concentrating and converting solar energy is provided, which device has at least one beam splitter of a planar configuration for deflecting solar radiation and at least two devices for the conversion of solar energy which are disposed offset relative to the beam splitter with respect to the direction of incidence of the solar radiation. The beam splitter thereby has, on the side orientated towards or away from the solar radiation, structuring which does not vary in translation relative to an axis and which deflects solar radiation which is incident on the beam splitter by means of light refraction onto the at least two devices for the conversion of solar energy. The beam splitter is thereby configured as a planar disc or plate.

There should be understood by structuring which does not vary in translation that the cross-section of the beam splitter remains essentially unchanged over the length of the beam splitter, i.e. in the propagation direction perpendicular to the cross-sectional profile.

An essential advantage of the present invention is based on the fact that, relative to concentrators in which the deflection of the radiation is based on total reflection, structures at an acute angle, i.e. structures having an edge angle of 60°, are not absolutely necessary, instead also flatter structures, i.e. structures having smaller edge angles, can be achieved. This has the essential advantage that structures of this type can be shaped substantially more easily.

Furthermore, the concentrator according to the invention has the advantage, relative to systems based on total reflection, that a deviation from an edge angle of 60°, which would lead necessarily to reflection losses during the total reflection, is not critical here in the present case so that also error tolerances in the production of the structures are acceptable here.

It is preferred that the structuring consists of a plurality of structural elements which repeat periodically over the entire surface.

Another preferred alternative provides that the structuring consists of a plurality of differing structural elements, the individual structural elements being coordinated to each other such that at least partial concentration of the deflected radiation onto the active surface is effected.

The structuring is preferably configured in the form of essentially equal-sided prisms. If the prisms are disposed on the side orientated away from the solar radiation, then they preferably have a base angle (edge angle) in the range of 10° to 40°, preferably of 20° to 35°.

If the prisms are disposed on the side orientated towards the solar radiation, then these preferably have a base angle (edge angle) in the range of 10° to 70°, particularly preferred of 20° to 60°.

A preferred embodiment provides that the base angles of the prisms are varied such that at least partial concentration of the deflected radiation is effected.

The beam splitter preferably consists of a structurable material or material composite, the transmission of which is at least 85% in the wavelength range of 400 to 1,100 nm or essentially comprises this. Preferably the material is made of glass and/or organic materials, in particular fluorine-, acrylate- or silicone polymers, or essentially comprises this. It is also possible to use multilayer composite systems as beam splitter. According to the invention, the coating or layer of the beam splitter which is orientated towards or away from the at least one photovoltaically active surface then has the structuring.

Furthermore, it is preferred that the structuring of the beam splitter has essentially the same structural depth over the entire surface in the direction of the surface normal to the surface which is preferably in the range of 10 μm to 20 mm, particularly preferred in the range of 50 μm to 5 mm.

The structuring can thereby have been introduced by casting, injection moulding, extrusion and/or embossing.

Likewise, the beam splitter can have a spectrally selective transmission in favour of the photovoltaically usable spectral component, inter alia with maximum transmissions in the range of 400 nm to 1,100 nm.

A further preferred embodiment provides that the beam splitter has an antireflective coating on the side orientated towards and/or away from the solar radiation.

The device for conversion of solar energy preferably concerns solar cells, solar modules or thermal solar collectors.

Preferably, the device for concentrating and converting solar energy has in addition an arrangement for monoaxial or biaxial trackability relative to the position of the sun. As a result, it is made possible that the concentrator is disposed between two devices for the conversion of solar energy, e.g. two solar modules, and the output of the solar modules can be increased by the tracking system. Likewise, solar radiation which would impinge on the inactive frame of the solar modules can be used with the device according to the invention.

The previously described concentrators for concentrating solar radiation are used on photovoltaically active components. Thus the concentrators can be used for constructing concentrating photovoltaic systems. Commercially available silicon cells or silicon modules can be used as cells or modules for non-concentrating use. If these photovoltaic modules are tracked, they can be mounted also on normal solar trackers.

Likewise it is possible that the concentrators according to the invention are used in conjunction with thermal solar collectors which cause conversion of solar energy into heat.

The subject according to the invention is intended to be explained in more detail with reference to the subsequent Figures without wishing to restrict said subject to the special embodiments shown here.

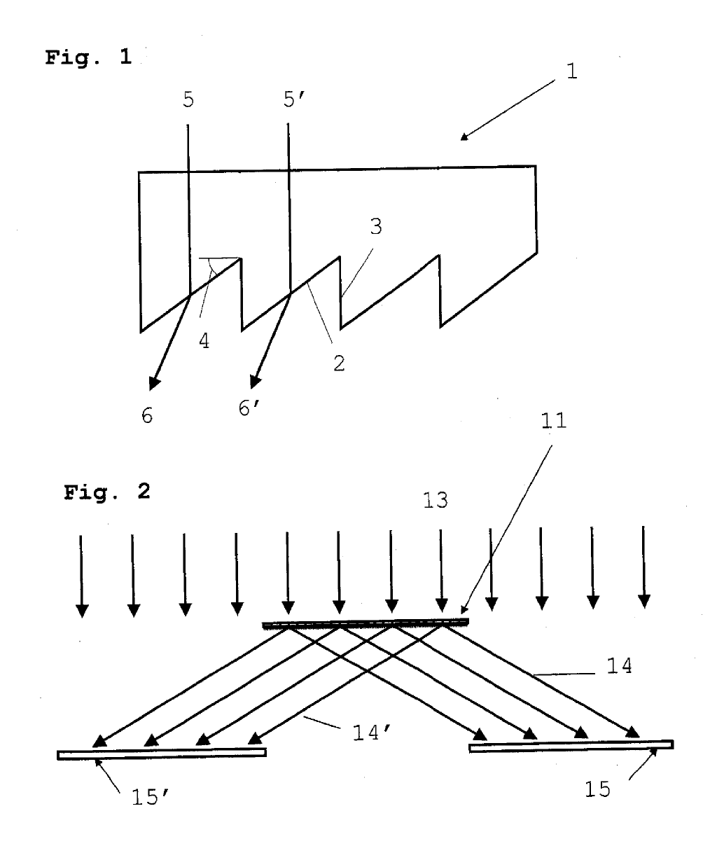

FIG. 1 shows a light-refractive Fresnel beam deflector according to the state of the art with reference to a schematic representation.

FIG. 2 shows a concentrator according to the invention with reference to a schematic representation.

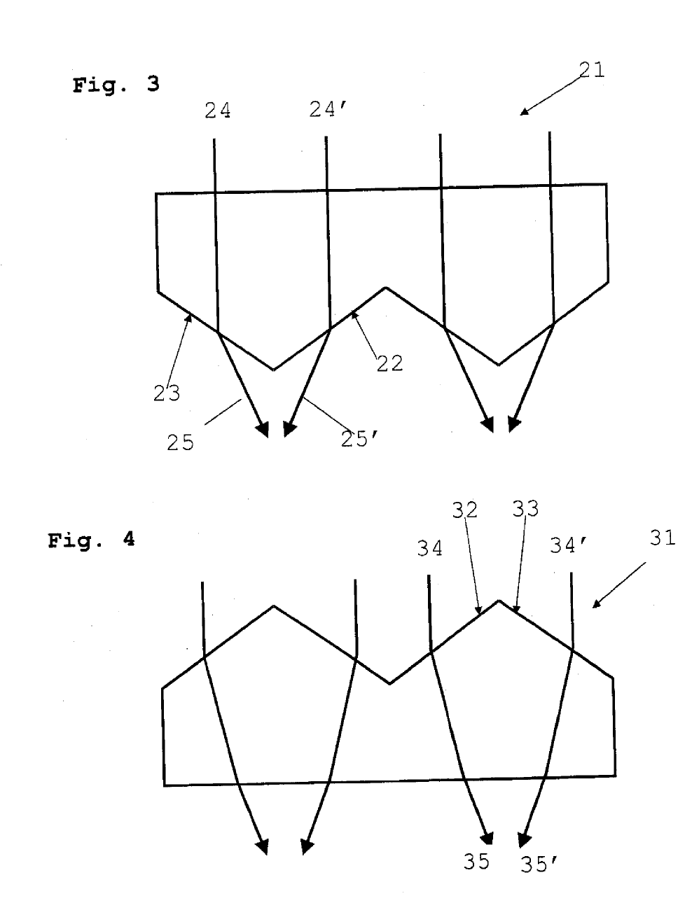

FIG. 3 shows the arrangement of a plurality of beam splitters in conjunction with corresponding axis surfaces with reference to a schematic representation.

FIG. 4 shows a second variant of a concentrator according to the invention with reference to a schematic representation.

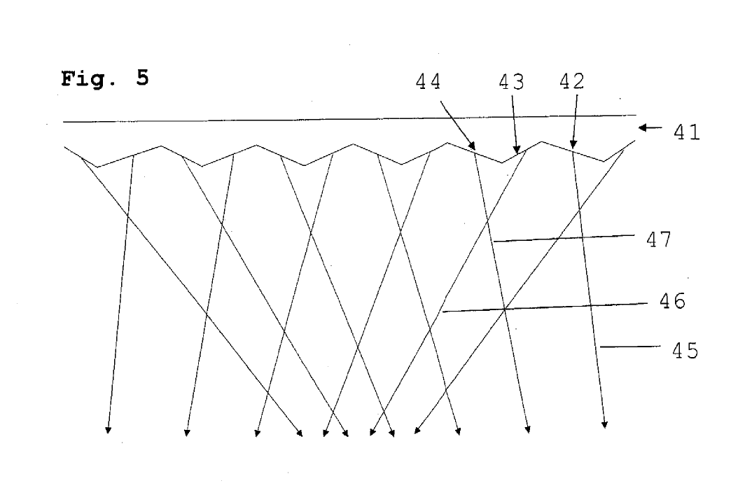

FIG. 5 shows a further variant according to the invention of a beam splitter with reference to a schematic representation.

In FIG. 1, a beam deflector 1, as is known from the state of the art, is represented. Structuring 2 is disposed here on the side of the beam deflector 1 which is orientated away from the solar radiation. In addition to the active surfaces 2, the structuring also has inactive surfaces, i.e. steps 3. Incident solar radiation 5 or 5′ is deflected onto the active surfaces, this deflected radiation 6 or 6′ can then be further used. The disadvantage of this embodiment can be attributed to the vertical inactive surfaces and also the acute angles between active and inactive surfaces. This makes economical production and also the use of economical materials difficult.

In FIG. 2, a concentrator according to the invention is illustrated which has a beam splitter 11 via which solar radiation 13 is deflected into a first beam bundle 14 and a second beam bundle 14′. The beam bundle 14 is thereby deflected onto the active surface 15, e.g. a solar cell surface, whilst the second beam bundle 14′ is deflected onto the photovoltaically active surface 15′. With such an arrangement, a geometric concentration by the factor 1.5 can be achieved.

The arrangement, shown in FIG. 2, of a beam splitter and two photovoltaically active surfaces can be extended arbitrarily in both spatial directions, e.g. an array-like arrangement. In this case, a geometric concentration by the factor 2 is produced.

In FIG. 3, a variant according to the invention of a beam splitter 21 is represented, in which the structuring is disposed on the side orientated away from the solar radiation. The structuring hereby has active surfaces 22 and 23. Incident solar radiation 24 or 24′ is hereby refracted on the active surfaces and guided as deflected radiation 25 or 25′, for example to the solar modules. The edge angles of the structuring, i.e. of the prisms, are delimited, with a refractive index of the material of the beam splitter of n=1.5, to approx. 34° so that a maximum beam deflection of approx. 24° is produced. With larger edge angles, the reflection losses begin to increase.

In FIG. 4, a further embodiment according to the invention of a beam splitter 31 is represented, in which the structuring is disposed on the side of the beam splitter 31 which is orientated towards the solar radiation. Active surfaces 32 and 33 are also represented here. Incident solar radiation 34 and 34′ is refracted on the active surfaces 32 and 33 and also upon exit from the beam splitter 31 and guided as deflected radiation 35 and 35′ to the solar modules. In this arrangement, the maximum edge angle is at approx. 60°, with which a beam deflection of approx. 39° can be achieved. The large beam deflection consequently enables a more compact construction for concentrating PV systems.

In FIG. 5, a beam splitter 41 which has asymmetric edge angles of the prisms 42, 43 and 44 is represented. The deflected radiation 45, 46 or 47 is hence deflected and bundled, i.e. concentrated. Via the width of the structure and the gradual change in the prisms, higher concentrations can thus be achieved.

1. Device for concentrating and converting solar energy, comprising:
at least one beam splitter of a planar configuration for deflecting solar radiation; and
at least two devices to convert solar energy which are disposed offset relative to the beam splitter with respect to the direction of incidence of the solar radiation,
wherein the beam splitter comprises, on the side orientated one of towards or away from the solar radiation, structuring which does not vary in translation relative to an axis and which is adapted to deflect solar radiation which is incident on the beam splitter via light refraction onto the at least two devices to convert solar energy.

2. Device according to claim 1,
wherein the structuring comprises one of a plurality of structural elements which repeat periodically over the entire surface or a plurality of differing structural elements, the individual structural elements being coordinated to each other such that at least partial concentration of the deflected radiation is effected.

3. Device according to claim 1, wherein the structuring is configured in the form of essentially equal-sided prisms.

4. Device according to claim 3,
wherein the prisms are disposed on the side orientated away from the solar radiation, the prisms comprising a base angle in the range of 10° to 40°
or the prisms are disposed on the side orientated towards the solar radiation, the prisms then comprising a base angle in the range of 10° to 70°.

5. Device according to claim 1
wherein the beam splitter comprises at least one of a structurable material and material composite, the transmission of which is at least 85% in the wavelength range of 400 to 1,100 nm.

6. Device according to claim 5,
wherein the material comprises at least one of a group including glass and organic materials, including fluorine-, acrylate-, silicone polymers and compounds thereof.

7. Device according to claim 1,
wherein the structuring has essentially the same structural depth over the entire surface in the direction of the surface normal to the surface in the range of 10 μm to 20 mm, in particular of 500 μm to 5 mm.

8. Device according to claim 1,
wherein the structuring is formed by a process comprising at least one of casting, injection moulding, extrusion and embossing.

9. Device according to claim 1,
wherein the beam splitter has a spectrally selective transmission in favor of the photovoltaically usable spectral component.

10. Device according to claim 1,
wherein the beam splitter has an antireflective coating on the side orientated towards and/or away from the solar radiation.

11. Device according to claim 1,
wherein the device to convert solar energy comprises at least one of a group including a solar cell, a solar module and a thermal solar collector.

12. Device according to claim 1,
wherein the device has an arrangement adapted to provide at least one of a group including monoaxial and biaxial trackability relative to the position of the sun.
